(19) United States
(12) Patent Application Publication
(10) Pub. No.: US 2026/0173683 A1
(43) Pub. Date: Jun. 18, 2026

(54) DISPLAY APPARATUS AND METHOD OF MANUFACTURING SAME

(71) Applicant: LG Display Co., Ltd., Seoul (KR)

(72) Inventor: Young Kyun MOON, Paju-si (KR)

(73) Assignee: LG Display Co., Ltd., Seoul (KR)

(21) Appl. No.: 19/326,536

(22) Filed: Sep. 11, 2025

(30) Foreign Application Priority Data
Dec. 18, 2024 (KR) 10-2024-0189528

(51) Int. Cl. H10K 59/131; H10K 59/12; H10K 59/122; H10K 59/80

(52) U.S. Cl. CPC H10K 59/131; H10K 59/1201; H10K 59/122; H10K 59/80517; H10K 59/873; H10K 59/8792

(57) ABSTRACT

A display apparatus includes a substrate including an active area having pixel areas and a bezel area around the active area, a mask layer in the bezel area and having a plurality of open portions, a planarization layer on the substrate including the mask layer, an anode of a light-emitting element on the planarization layer of each pixel area, a low voltage power line on the planarization layer of the bezel area to overlap the mask layer, a bank insulating film on the planarization layer to expose the anode and the low voltage power line, an emission unit of the light-emitting element over the active area and the low voltage power line of the bezel area, portions of the emission unit corresponding to the open portions, and a cathode of the light-emitting element on the emission unit of the light-emitting element and connected to the low voltage power line.

This application claims the benefit of Korean Patent Application No. 10-2024-0189528, filed on Dec. 18, 2024, which is hereby incorporated by reference as if fully set forth herein.

### BACKGROUND

### Technical Field

The present disclosure relates to a display apparatus, and more specifically, to a display apparatus capable of achieving a narrow bezel and a method of manufacturing the same.

### Discussion of the Related Art

Image display apparatuses that display various types of information on screens are core technology of the information and communication era, and are developing into thinner, lighter, more portable, and higher performance display apparatuses. Accordingly, display apparatuses that can be manufactured in a lightweight and thin structure are in the spotlight.

Specific examples of such display apparatuses include a liquid crystal display (LCD) apparatus, a quantum dot display (QD) apparatus, a field emission display (FED) apparatus, and an organic light emitting diode (OLED) display apparatus.

An organic light emitting display apparatus is a spontaneous emission type display apparatus and is not only advantageous in terms of power consumption due to low voltage operation, but also excellent in color expression, response speed, viewing angle, and contrast ratio (CR).

Research is being conducted to increase the active area and reduce the bezel area, which is a non-active area, in such organic light emitting display apparatuses.

However, it is difficult to achieve a narrow bezel structure because the process margin of a common emission layer in the bezel area needs to be considered in order to secure display performance.

### SUMMARY

Accordingly, embodiments the present disclosure are directed to a display apparatus and a method of manufacturing the same that substantially obviate one or more problems due to limitations and disadvantages of the related art.

An aspect of the present disclosure is to provide a display apparatus in which a cathode is in contact with a power line in a process margin area of a common emission layer in a bezel area, and a method of manufacturing the same.

Another aspect of the present disclosure is to provide a display apparatus and a method of manufacturing the same for achieving a narrow bezel by connecting a cathode and a power line in a process margin area of a common emission layer in a bezel area to delete the process margin area of the common emission layer in the bezel area.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display apparatus comprises a substrate including an active area having a plurality of pixel areas and a bezel area around the active area, a mask layer positioned on the substrate in the bezel area and having a plurality of open portions, a planarization layer formed on the entire surface of the substrate including the mask layer, an anode of a light-emitting element positioned on the planarization layer of each of the plurality of pixel areas, a low voltage power line positioned on the planarization layer of the bezel area to overlap the mask layer, a bank insulating film positioned on the planarization layer to expose the anode and the low voltage power line, an emission unit of the light-emitting element positioned over the active area and the low voltage power line of the bezel area, portions of the emission unit corresponding to the plurality of open portions of the mask layer being removed, and a cathode of the light-emitting element positioned on the emission unit of the light-emitting element and electrically connected to the low voltage power line.

In another aspect, a method of manufacturing a display apparatus comprises forming a thin film transistor in each pixel area of a substrate including an active area having a plurality of pixel areas and a bezel area around the active area, forming a mask layer having a plurality of open portions on the substrate in the bezel area, forming a planarization layer on the entire surface of the substrate including the thin film transistor and the mask layer, forming an anode of a light-emitting element on the planarization layer of each of the plurality of pixel areas such that the anode is electrically connected to the thin film transistor, forming a low voltage power line on the planarization layer of the bezel area such that the low voltage power line overlaps the mask layer, forming a bank insulating film on the planarization layer to expose the anode and the low voltage power line, forming an emission unit of the light-emitting element over the active area and the low voltage power line of the bezel area, removing portions of the emission unit of the light-emitting element corresponding to the plurality of open portions of the mask layer by radiating a laser from the side of the substrate using the mask layer as a mask, and forming a cathode of the light-emitting element on the emission unit of the light-emitting element and the bezel area such that the cathode is electrically connected to the low voltage power line.

Specific details of other embodiments are included in the detailed description and drawings.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles of the present disclosure. In the drawings:

FIG. 1 is a block diagram showing a display apparatus according to an embodiment of the present disclosure;

FIG. 2 is a circuit diagram showing a pixel circuit in the display apparatus according to an embodiment of the present disclosure;

FIG. 3 is a cross-sectional view illustrating a tolerance margin area of a bezel area of a display panel according to an embodiment of the present disclosure;

FIG. 4 is a cross-sectional view of a display panel according to another embodiment of the present disclosure;

FIG. 5 to FIG. 7 are plan views of mask layers according to various embodiments of the present disclosure;

FIG. 8A to FIG. 8E are cross-sectional views illustrating a method of manufacturing the display apparatus according to an embodiment of the present disclosure;

FIG. 9 is an enlarged cross-sectional view of one open portion 228b of a mask layer 228, and a low voltage power line EVSS, an emission unit 320, and a cathode 330 formed according thereto according to an embodiment of the present disclosure;

FIG. 10 is an enlarged cross-sectional view of one open portion 228b of the mask layer 228, and the low voltage power line EVSS, the emission unit 320, and the cathode 330 formed according thereto according to another embodiment of the present disclosure; and

FIG. 11 is an enlarged cross-sectional view of one open portion 228b of the mask layer 228, and the low voltage power line EVSS, the emission unit 320, and the cathode 330 formed according thereto according to another embodiment of the present disclosure.

### DETAILED DESCRIPTION

Hereinafter, embodiments of the present disclosure will be described in detail with reference to the attached drawings. Throughout the specification, the same reference numerals refer to substantially the same components.

In the following description, if a detailed description of known techniques associated with the present disclosure would unnecessarily obscure the gist of the present disclosure, detailed description thereof will be omitted. In addition, the component names used in the description below are selected for ease of specification writing and may differ from the names of components of the actual product.

The shapes, sizes, ratios, angles, numbers, and the like, which are illustrated in the drawings in order to describe various embodiments of the present disclosure, are merely given by way of example, and therefore, the present disclosure is not limited to the illustrations in the drawings. Throughout the specification, the like reference numerals refer to substantially the like components.

In the present disclosure, when the terms “comprise”, “include”, and the like are used, other elements may be added unless the term “only” is used. The singular forms are intended to include the plural forms as well, unless the context clearly indicates otherwise.

In interpretation of a component included in various embodiments of the present disclosure, the component is interpreted as including an error range unless otherwise explicitly described.

In describing various embodiments of the present disclosure, when describing a positional relationship, for example, when the positional relationship between two parts is described using “on”, “above”, “below”, “beside”, or the like, one or more other parts may be located between the two parts unless the term “directly” or “closely” is used.

In describing various embodiments of the present disclosure, when describing a temporal relationship, for example, when describing a temporal chronological relationship using the terms “after”, “following”, “next”, “before”, etc., cases that are not continuous may also be included unless “immediately” or “directly” is used.

In the description of the various embodiments of the present disclosure, although terms such as “first” and “second” may be used to describe various elements, these terms are merely used to distinguish the same or similar elements from each other. Therefore, in the present specification, an element modified by “first” may be the same as an element modified by “second” within the technical scope of the present disclosure unless otherwise mentioned.

Features within the various embodiments of the present disclosure may be partially or wholly combined, and may technically operate or drive in connection, and various embodiments may be implemented independently of each other or may be implemented in combination.

Hereinafter, a display apparatus according to an embodiment of the present disclosure will be described with reference to the drawings.

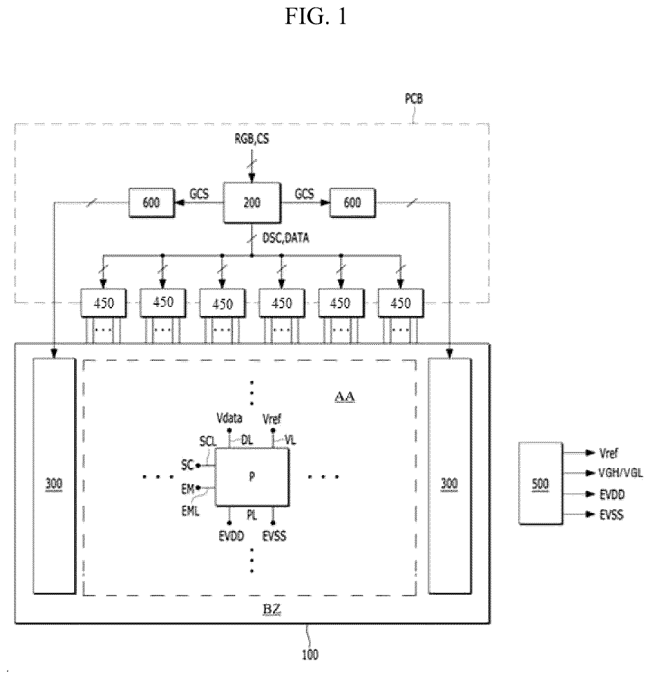

FIG. 1 is a block diagram showing a display apparatus according to an embodiment of the present disclosure.

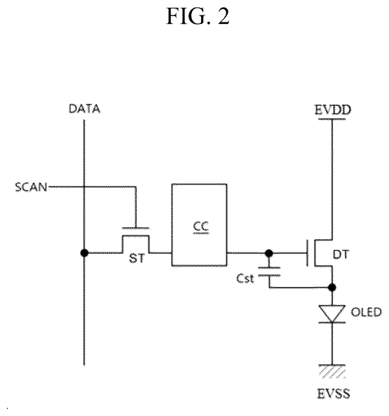

FIG. 2 is a circuit diagram of a pixel included in the display apparatus according to an embodiment of the present disclosure.

As illustrated in FIG. 1, a display apparatus according to an embodiment of the present disclosure includes a display panel 100 including a plurality of pixels P, a controller 200, a gate driving circuit 300 that supplies a gate signal to each of the plurality of pixels P, a data driving circuit 450 that supplies a data signal to each of the plurality of pixels P, a power supply 500 that supplies power required to drive each of the plurality of pixels P, a level shifter 600 that adjusts the level of a gate signal applied to the gate driving circuit 300, and a sensing unit (not illustrated in the drawing) that detects deterioration of the plurality of pixels P. Here, the controller 200, the gate driving circuit 300, the data driving circuit 450, and the sensing unit may be collectively referred to as a control unit.

The display panel 100 may include an active area AA in which pixels P are positioned, and a bezel area BZ disposed to surround the active area AA. The active area AA may have a plurality of pixel areas. The gate driving circuit 300 and the data driving circuit 450 may be disposed in the bezel area BZ. The gate driving circuit 300 may be disposed in the active area AA.

In the display panel 100, a plurality of gate lines SCL and EML intersect a plurality of data lines DL, and the pixels P are connected to the gate lines SCL and EML and the data lines DL. Specifically, one pixel P receives a gate signal from the gate driving circuit 300 through gate lines SCL and EML, receives a data signal from the data driving circuit 450 through a data line DL, and receives a high-level driving voltage EVDD and a low-level driving voltage EVSS from the power supply 500 through a driving voltage line PL.

Here, a scan signal SC and an emission control signal EM are supplied through the gate lines SCL and EML, and a data voltage Vdata is supplied through the data lines DL. In addition, according to various embodiments, the gate lines SCL and EML may include a plurality of scan lines SCL through which the scan signal SC is supplied and an emission control line EML through which the emission control signal EM is supplied. In addition, the plurality of pixels P may additionally include a power line VL to receive a reference voltage Vref or an initialization voltage Vini.

TFTs constituting each pixel P may be implemented as oxide TFTs including an oxide semiconductor layer. The oxide TFT may be advantageous for the large-area display panel 100 when considering electron mobility, process deviation, etc. The present disclosure is not limited thereto, and a semiconductor layer of a TFT may be formed of amorphous silicon, polysilicon, or the like.

In addition, each pixel P includes a light-emitting element (organic light-emitting diode) OLED and a pixel circuit that controls operation of the light-emitting element OLED. Here, the light-emitting element OLED may be composed of an anode, a cathode, and an emission layer provided between the anode and the cathode.

Each pixel P may include a switching transistor ST, a driving transistor DT, a compensation circuit CC, a light-emitting element OLED, and a storage capacitor Cst, as illustrated in FIG. 2.

The light-emitting element OLED may operate to emit light according to a driving current formed by the driving transistor DT.

The switching transistor ST may perform a switching operation such that a data signal Vdata supplied through a data line DL is stored as a data voltage in the storage capacitor Cst in response to a scan signal SC or EM supplied through a gate line SCL or EML. The storage capacitor may maintain the data voltage for one frame.

The driving transistor DT may operate to allow a constant driving current to flow between the high-level power line EVDD and the low-level power line EVSS in response to the data voltage stored in the storage capacitor Cst.

The compensation circuit CC is a circuit for compensating for the threshold voltage of the driving transistor DT, and the compensation circuit CC may include one or more thin film transistors and a capacitor. The configuration of the compensation circuit CC may vary depending on the compensation method.

For example, the pixel P illustrated in FIG. 2 is configured as a 2T (Transistor) 1C (Capacitor) structure including the switching transistor ST, the driving transistor DT, the storage capacitor Cst, and the light-emitting element OLED, but if the compensation circuit CC is added, the pixel P may be configured in various structures such as 3T1C, 4T2C, 5T2C, 6T1C, 6T2C, 7T1C, 7T2C, and 8T1C.

The display panel 100 may be implemented as a non-transparent display panel or a transparent display panel. The transparent display panel may be applied to a transparent display apparatus in which an image is displayed on the screen and the actual background is visible. The display panel 100 may be manufactured as a flexible display panel. The flexible display panel may be implemented as an organic light emitting display panel using a plastic substrate.

Each pixel P may be a red pixel, a green pixel, or a blue pixel for color implementation. Each pixel P may further be a white pixel. Each pixel P includes a pixel circuit.

Touch sensors may be provided on the display panel 100. Touch input may be sensed using separate touch sensors or may be sensed through the pixels P. The touch sensors may be implemented as on-cell type or add on type touch sensors disposed on the screen of the display panel 100 or as in-cell type touch sensors built into the display panel 100.

The controller 200 processes image data RGB input from the outside such that the image data RGB is suitable for the size and resolution of the display panel 100 and supplies the processed image data DATA to the data driving circuit 450. The controller 200 generates a gate control signal GCS and a data control signal DCS using timing signals CS input from the outside, such as a dot clock signal, a data enable signal DE, a horizontal synchronization signal Hsync, and a vertical synchronization signal Vsync. By supplying the generated gate control signal GCS and data control signal DCS to the gate driving circuit 300 and the data driving circuit 450, the controller 200 controls the gate driving circuit 300 and the data driving circuit 450.

The controller 200 may be configured to be combined with various processors, such as a microprocessor, a mobile processor, and an application processor depending on the device to be mounted in the display apparatus.

A host system may be any one of a TV system, a set-top box, a navigation system, a personal computer (PC), a home theater system, a mobile device, a wearable device, and a vehicle system.

The controller 200 may multiply an input frame frequency by i and control the operation timing of a display panel driver at a frame frequency of input frame frequency×i (i being a positive integer greater than 0) Hz. The input frame frequency may be 60 Hz in the case of NTSC (National Television Standards Committee) and 50 Hz in the case of PAL (Phase-Alternating Line).

The controller 200 generates signals such that the pixels P can be driven at various refresh rates. That is, the controller 200 generates signals related to driving such that the pixels P can be driven in a variable refresh rate (VRR) mode or can switch between a first refresh rate and a second refresh rate. For example, the controller 200 may drive the pixels P at various refresh rates by simply changing the rate of the clock signal, generating synchronization signals such that a horizontal blank period or a vertical blank period is created, or driving the gate driving circuit 300 in a mask manner.

The controller 200 generates the gate control signal GCS for controlling the operation timing of the gate driving circuit 300 and the data control signal DCS for controlling the operation timing of the data driving circuit 450 on the basis of a timing signal CS received from the host system. The controller 200 controls the operation timing of the display panel driver to synchronize the gate driving circuit 300 and the data driving circuit 450.

The data driving circuit 450 receives image data DATA and the data control signal DCS from the controller 200. In response to the data control signal DCS from the controller 200, the data driving circuit 450 converts the image data DATA into a gamma compensation voltage to generate a data voltage Vdata, and supplies the data voltage Vdata to the data lines DL of the display panel 100 in synchronization with a scan signal SC. The data driving circuit 450 may be connected to the data lines of the display panel 100 by a COG (Chip On Glass) process or a TAB (Tape Automated Bonding) process.

The gate driving circuit 300 operates according to the gate control signal GCS input from the level shifter 600 to generate a gate signal. Then, the gate signal is sequentially supplied to the gate lines SCL or EML. The gate driving circuit 300 may be formed directly on the lower substrate of the display panel 100 in a GIP (Gate driver In Panel) structure. The gate driving circuit 300 may be formed in an active area AA in which a screen is displayed on the display panel 100, or may be formed in a non-active area outside the active area AA. The non-active area may include a bezel area BZ, or may be the same as the bezel area BZ. In the GIP structure, the level shifter 600 may be mounted on a printed circuit board (PCB) along with the controller 200.

The power supply 500 generates DC power required to drive the pixel array of the display panel 100 and the display panel driver using a DC-DC converter. The DC-DC converter may include a charge pump, a regulator, a buck converter, a boost converter, etc. The power supply 500 may receive a DC input voltage applied from the host system (not shown) and generate DC voltages such as gate-on voltages VGL, gate-off voltages VGH, the high-level driving voltage EVDD, and the low-level driving voltage EVSS. The gate-on voltages VGL and the gate-off voltages VGH are supplied to the level shifter 600 and the gate driving circuit 300. The high-level driving voltage EVDD and the low-level driving voltage EVSS are supplied commonly to the pixels P.

The level shifter 600 boosts a TTL (Transistor-Transistor-Logic) level voltage of the gate control signal GCS input from the controller 200 to the gate high voltage VGH and the gate low voltage VGL that can drive TFTs formed in the display panel 100 and supplies the boosted voltages to the gate driving circuit 300. The gate control signal GCS may include a start signal and a clock signal. The plurality of pixels P of the display panel 100 may include at least a first pixel, a second pixel, and a third pixel. The first pixel, the second pixel, and the third pixel may emit light of different colors. For example, the first pixel may be a red pixel, the second pixel may be a green pixel, and the third pixel may be a blue pixel.

The plurality of pixels P may have the same size or different sizes. The first pixel, the second pixel, and the third pixel may be designed to have different sizes in consideration of the lifespan of the light-emitting element OLED included in each of the first pixel, the second pixel, and the third pixel, color balance, or the like.

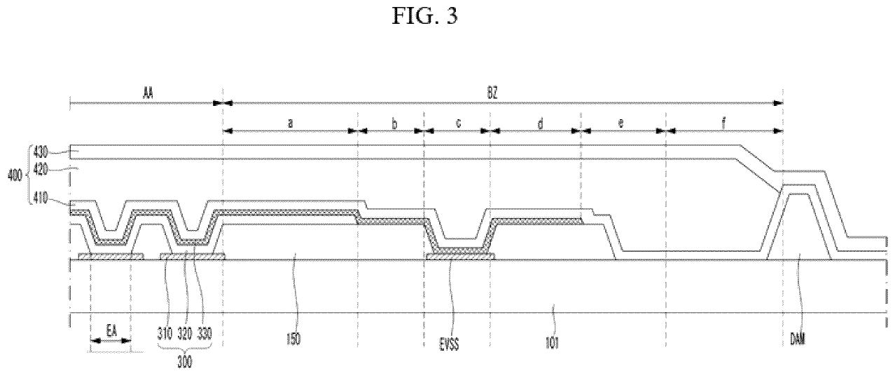

FIG. 3 is a cross-sectional view illustrating a tolerance margin area of the bezel area in the display panel according to an embodiment of the present disclosure.

The display panel according to an embodiment of the present disclosure may be divided into an active area AA and a bezel area BZ, as illustrated in FIG. 3.

In the active area AA of the display panel 100, a plurality of gate lines intersects a plurality of data lines, and the plurality of pixels are connected to the gate lines and the data lines.

As described in FIG. 1 and FIG. 2, the switching transistor ST, the driving transistor DT, the compensation circuit CC, the light-emitting element OLED, and the storage capacitor Cst are disposed in each pixel.

For example, the switching transistor ST, the driving transistor DT, the compensation circuit CC, and the storage capacitor Cst are disposed on a substrate 101 of each pixel area. In addition, a planarization layer (not shown in the drawing) may be disposed on the substrate 101 on which the switching transistor ST, the driving transistor DT, the compensation circuit CC, and the storage capacitor Cst are disposed. The planarization layer may be disposed in the active area AA and the bezel area BZ.

A light-emitting element 300 having an anode 310, an emission unit 320, and a cathode 330 sequentially laminated may be disposed on the planarization layer of each pixel area.

In each pixel area, the anode 310 may be disposed on the planarization layer and may be electrically connected to a driving transistor through a contact hole formed in the planarization layer. A low voltage power line EVSS may be disposed on the planarization layer of the bezel area BZ.

A bank insulating film 150 may be disposed on the planarization layer on which the anode 310 and the low voltage power line EVSS are formed. The bank insulating film 150 may define an emission area EA within each pixel area. For example, the emission area EA of each pixel area is exposed by the bank insulating film 150, and the remaining portion is covered by the bank insulating film 150.

In addition, the emission unit 320 is disposed on the anode 310 and the bank insulating film 150 to be in contact with the anode 310. The emission unit 320 may generate light having a luminance corresponding to a voltage difference between the anode 310 and the cathode 330. For example, the emission unit 320 may include an emission material layer (EML). The emission material layer may include an organic emission material, an inorganic emission material, or a hybrid emission material. For example, the display apparatus according to an embodiment of the present disclosure may be an organic light emitting display apparatus including an organic emission material. The emission unit 320 may have a multilayer structure. For example, the emission unit 320 may further include at least one of a hole injection layer (HIL), a hole transport layer (HTL), an electron transport layer (ETL), and an electron injection layer (EIL).

In the configuration of the emission unit 320, the emission material layer EML may be separately disposed for each pixel area, and at least one of the hole injection layer (HIL), the hole transport layer (HTL), the electron transport layer (ETL), or the electron injection layer (EIL) may be commonly disposed in the pixel areas. The hole injection layer (HIL), the hole transport layer (HTL), the electron transport layer (ETL), and the electron injection layer (EIL) may be referred to as a common emission layer. The common emission layer may extend to the bezel area.

The cathode 330 may be disposed on the emission unit 320. The cathode 330 may include a conductive material. The cathode 330 may include a different material from the anode 310.

The cathode 330 may extend to the bezel area BZ. The cathode 330 may be electrically connected to the low voltage power line EVSS in the bezel area BZ. For example, the cathode 330 may be electrically connected to the low voltage power line EVSS through a contact hole formed in the bank insulating film 150 in the bezel area BZ.

An encapsulation structure 400 that suppresses moisture penetration may be further provided on the emission element 300. The encapsulation structure 400 can block external moisture or oxygen from penetrating into the emission unit 320 which is vulnerable to external moisture or oxygen. To this end, the encapsulation structure 400 may have a multilayer structure. For example, the encapsulation structure 400 may include a first encapsulation layer 410, a second encapsulation layer 420, and a third encapsulation layer 430 which are sequentially laminated. The second encapsulation layer 420 may include a different material from the first encapsulation layer 410 and the third encapsulation layer 430. The second encapsulation layer 420 may include a material having relatively high fluidity. For example, the first encapsulation layer 410 and the third encapsulation layer 430 may be inorganic encapsulation layers made of inorganic insulating materials, and the second encapsulation layer 420 may be an organic encapsulation layer made of an organic insulating material.

The emission unit 320 and the cathode 330 are formed in the active area using an open metal mask (OMM). However, the bezel area is designed in consideration of the hardware (H/W) manufacturing tolerance of the open metal mask (OMM), the alignment tolerance of equipment, the tolerance of an in/out shadow length (a gap between the substrate and the mask, etc.), and the inkjet tolerance of the second encapsulation layer 420.

For example, the emission unit 320 may be formed only in the active area AA and may not be formed in the bezel area BZ. However, if the above-mentioned tolerance of the open metal mask for the emission unit 320 is not considered, the emission unit 320 may not be formed in the bezel area BZ. Therefore, considering the tolerances of the open metal mask for the emission unit 320, the emission unit 320 needs to also be formed in the bezel area BZ adjacent to the active area AA. Accordingly, the bezel area BZ is designed to have a first EL tolerance area a in which the emission unit 320 is formed and a second EL tolerance area b in which the emission unit 320 is not formed. The emission unit 320 may be positioned over the active area AA and the low voltage power line EVSS of the bezel area BZ.

In addition, the cathode 330 needs to be electrically connected to the low voltage power line EVSS in the bezel area BZ. If the above-mentioned tolerance of the open metal mask for the cathode 330 is not considered, the cathode 330 may not be electrically connected to the low voltage power line EVSS. Therefore, considering the tolerances of the open metal mask for the cathode 330, the bezel area BZ is designed to have a cathode contact area c in which the cathode 330 and the low voltage power line EVSS are connected, a first cathode tolerance area d in which the cathode 330 extends further outward than the cathode contact area c, and a second cathode tolerance area e in which the cathode 330 does not extend.

In addition, the bezel area BZ is designed to have an inkjet tolerance area f considering the inkjet tolerance of the second encapsulation layer 420.

As described above, the bezel area BZ includes the first EL tolerance area a, the second EL tolerance area b, the cathode contact area c, the first cathode tolerance area d, the second cathode tolerance area e, and the inkjet tolerance area f.

Therefore, the display panel according to an embodiment of the present disclosure has a limit in reducing the bezel area.

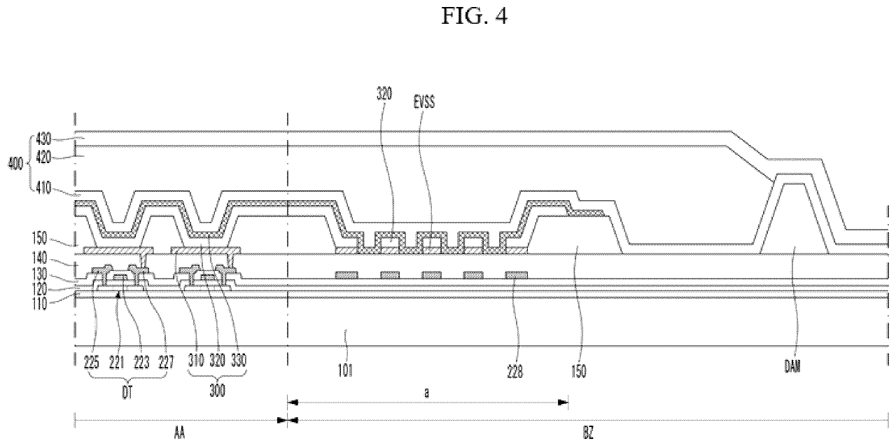

FIG. 4 is a cross-sectional view of a display panel according to another embodiment of the present disclosure.

In the display panel according to another embodiment of the present disclosure, as illustrated in FIG. 4, a substrate 101 of the display panel 100 is divided into an active area AA and a bezel area BZ. A buffer insulating film 110 may be formed on the substrate 101 of the active area AA and the bezel area BZ. The buffer insulating film 110 is provided to block moisture, etc. that may penetrate from the outside, and may be formed by laminating a silicon oxide (SiO₂) film and/or a silicon nitride (SiNx) film in multiple layers.

A transistor may be disposed in each pixel area of the active area AA. The transistor may be disposed below the anode 310 of each light-emitting element 300. The transistor illustrated in FIG. 4 represents the driving transistor DT illustrated in FIG. 2. Each driving transistor DT may include an active layer 221, a gate electrode 223, a source electrode 227, and a drain electrode 225.

The active layer 221 of each driving transistor DT may be disposed on the buffer insulating film 110. The active layer 221 may include a channel region, a source region disposed on one side of the channel region, and a drain region disposed on the other side of the channel region.

The active layer 221 may include a polycrystalline semiconductor. The source region and the drain region are conductive regions in which a polycrystalline semiconductor material is doped with impurity ions of Group 5 or Group 3, such as phosphorus (P) or boron (B), at a predetermined concentration. The channel region is a region where the polycrystalline semiconductor material maintains an intrinsic state and can provide a path for movement of electrons or holes.

In another embodiment, the active layer 221 may contain an oxide semiconductor and include an intrinsic channel region that is not doped with impurities and conductive source and drain regions doped with impurities. When the active layer 221 is made of an oxide semiconductor material, a light-shielding layer (not shown in the drawing) overlapping the active layer 221 may be further provided.

A gate insulating film 120 may be disposed on the entire surface of the substrate 101 on which the active layer 221 is formed. The gate insulating film 120 may be formed by laminating inorganic layers such as a silicon oxide (SiO₂) film or a silicon nitride (SiNx) film in a single structure or multilayer structure.

The gate electrode 223 may be disposed on the gate insulating film 120 on the upper side of the active layer 221. The gate electrode 223 may be made of a metal material. For example, the gate electrode 223 may be a single layer or multilayer made of one or more of molybdenum (Mo), aluminum (Al), chromium (Cr), gold (Au), titanium (Ti), nickel (Ni), neodymium (Nd), and copper (Cu), and an alloy thereof, but the present disclosure is not limited thereto.

An interlayer insulating film 130 may be disposed on each gate electrode 223. The interlayer insulating film 130 may be made silicon oxide (SiO₂), silicon nitride (SiNx), or the like.

The drain electrode 225 and the source electrode 227 of the transistor may be disposed on the interlayer insulating film 130 of each pixel area. The drain electrode 225 and the source electrode 227 may be electrically connected to the drain region and the source region of the active layer 221 through contact holes formed in the interlayer insulating film 130. The drain electrode 225 and the source electrode 227 may include a conductive material. For example, the drain electrode 225 and the source electrode 227 may include a metal such as aluminum (Al), chromium (Cr), copper (Cu), molybdenum (Mo), titanium (Ti), or tungsten (W). The drain electrode 225 and the source electrode 227 may be insulated from the gate electrode 223. The drain electrode 225 and the source electrode 227 may include a different material from the gate electrode 223.

In the bezel area BZ, a mask layer 228 may be formed of the same material as the drain electrode 225 and the source electrode 227 on the interlayer insulating film 130. However, the present disclosure is not limited thereto. The mask layer 228 may be formed of a different material from the drain electrode 225 and the source electrode 227. The mask layer 228 may be formed of the same material as the gate electrode 223. The mask layer 228 may be disposed in the first EL tolerance area a of the bezel area BZ described in FIG. 3. As an example, the bezel area BZ may have a first area in which the mask layer 228, the low voltage power line EVSS, and the emission unit 320 of the light-emitting element 300 are disposed, a second area in which the cathode 330 extends, and a third area in which the cathode 330 does not extend sequentially from the active area AA to the outermost side.

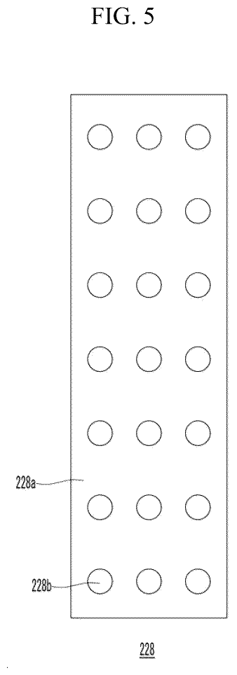

FIG. 5 to FIG. 7 are plan views of the mask layer 228 according to various embodiments of the present disclosure.

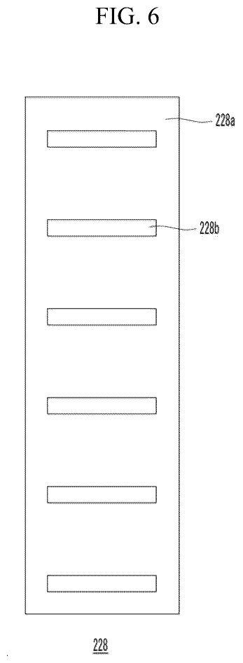

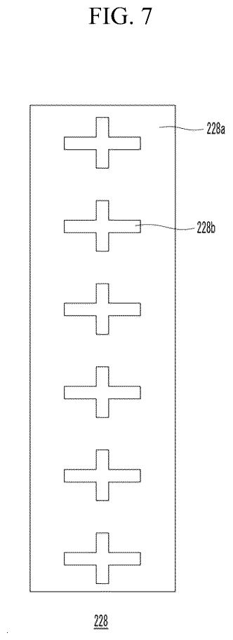

The mask layer 228 may be formed in various shapes, as illustrated in FIG. 5 to FIG. 7. The mask layer 228 may have a plurality of open portions 228b taking various forms and disposed in a mask body 228a. For example, as illustrated in FIG. 5, each of the open portions 228b may be formed in a circular shape. As illustrated in FIG. 6, each of the open portions 228b may be formed in a rectangular shape. As illustrated in FIG. 7, each of the open portions 228b may be formed in a cross shape.

A planarization film (or planarization layer) 140 may be disposed on the entire surface of the substrate including the driving transistor DT and the mask layer 228 disposed as described above. The planarization film 140 may eliminate steps caused by the driving transistor DT and the mask layer 228. For example, the drain electrode 225, the source electrode 227, and the mask layer 228 of each pixel area may be covered by the planarization film 140. The upper surface of the planarization film 140 facing the substrate 101 may be flat. For example, the upper surface of the planarization film 140 may be parallel to the upper surface of the substrate 101. The planarization film 140 may include an insulating material. The planarization film 140 may include a material having relatively high fluidity. For example, the planarization film 140 may be an organic insulating film made of an organic insulating material.

The light-emitting element 300 may be disposed on the planarization film 140 of each pixel area. The light-emitting element 300 of each pixel area may emit light representing a specific color. The light-emitting element 300 may include the anode 310, the emission unit 320, and the cathode 330. The light-emitting element 300 of each pixel area may overlap the emission area EA defined within the corresponding pixel area. For example, the anode 310, the emission unit 320, and the cathode 330 of each pixel area may be sequentially laminated on a portion of the planarization film 140 of the corresponding pixel area exposed by the bank insulating film 150.

Each anode 310 may be independently disposed on the planarization film 140 of each pixel area. Each anode 310 may be electrically connected to the source electrode 227 of the driving transistor DT through a contact hole formed in the planarization film 140. The anode 310 may include a conductive material. The anode 310 may include a material having relatively high reflectivity. For example, the anode 310 may include a metal such as aluminum (Al) or silver (Ag). The anode 310 may have a multilayer structure. For example, the anode 310 may have a structure in which a reflective electrode made of a metal is positioned between transparent electrodes made of transparent conductive materials such as ITO and IZO.

The low voltage power line EVSS may be disposed on the planarization film 140 of the bezel area BZ. The low voltage power line EVSS may overlap with the mask layer 228. The low voltage power line EVSS may be disposed in the first EL tolerance area a of the bezel area BZ described in FIG. 3. For example, the low voltage power line EVSS may be formed of the same material as the anode 310. The low voltage power line EVSS may be formed of a different material from the anode 310.

The bank insulating film 150 may be formed on the planarization film 140 on which the anode 310 and the low voltage power line EVSS are formed. The bank insulating film 150 may be formed on the planarization film 140 to cover the edges of each anode 310. The bank insulating film 150 may define the emission area EA within each pixel area. For example, the anode 310 overlapping the emission area EA of each pixel area may be exposed by the bank insulating film 150. The emission area EA of each pixel area may be surrounded by the bank insulating film 150. The anode 310 of each pixel area may be insulated from the anode 310 of an adjacent pixel area by the bank insulating film 150. The bank insulating film 150 may be formed on the planarization film 140 to cover the edges of the low voltage power line EVSS. For example, the low voltage power line EVSS may be exposed by the bank insulating film 150. The low voltage power line EVSS may be surrounded by the bank insulating film 150. The bank insulating film 150 may include an insulating material. For example, the bank insulating film 150 may be an organic insulating film made of an organic insulating material. The bank insulating film 150 may include a different material from the planarization film 140.

The bank insulating film 150 may form a dam DAM at the outermost edge of the bezel area BZ. The dam DAM may be formed higher than the bank insulating film 150 disposed in the active area AA and the bezel area BZ.

The emission unit 320 may be disposed to extend to the first EL tolerance area a of the bezel area BZ described in FIG. 3 as well as the active area AA. The emission unit 320 may be disposed on each anode 310 and the bank insulating film 150. The emission unit 320 may also be disposed on the low voltage power line EVSS exposed by the bank insulating film 150.

For example, the emission unit 320 may include an emission material layer (EML). The emission material layer may include an organic emission material, an inorganic emission material, or a hybrid emission material. For example, the display apparatus according to an embodiment of the present disclosure may be an organic light emitting display apparatus including an organic emission material. The emission unit 320 may have a multilayer structure. For example, the emission unit 320 may further include at least one of a hole injection layer (HIL), a hole transport layer (HTL), an electron transport layer (ETL), and an electron injection layer (EIL). Accordingly, in the display apparatus according to another embodiment of the present disclosure, the efficiency of the emission unit 320 can be improved.

The emission material layer (EML) of the emission unit 320 may be independently disposed on the anode 310 of the emission area EA of each pixel area. At least one of the hole injection layer (HIL), the hole transport layer (HTL), the electron transport layer (ETL), and the electron injection layer (EIL) of the emission unit 320 may be commonly disposed in all pixel areas. That is, at least one of the hole injection layer (HIL), the hole transport layer (HTL), the electron transport layer (ETL), and the electron injection layer (EIL) of the emission unit 320 may be commonly disposed on the bank insulating film 150 not only in the active area AA but also in the first EL tolerance area a of the bezel area BZ described in FIG. 3.

The emission unit 320 on the upper side of the mask layer 228 may be selectively removed. For example, portions of the emission unit 320 corresponding to the plurality of open portions 228b of the mask layer 228 may be selectively removed.

In another embodiment, not only the emission unit 320 on the upper side of the mask layer 228 but also the low voltage power line EVSS may be selectively removed. For example, portions of the emission unit 320 and the low voltage power line EVSS corresponding to the plurality of open portions 228b of the mask layer 228 may be selectively removed.

The cathode 330 may be disposed on the emission unit 320. The cathode 330 may include a conductive material. The cathode 330 may include a different material from the anode 310. The transmittance of the cathode 330 may be greater than the transmittance of the anode 310. For example, the cathode 330 may be a transparent electrode made of a transparent conductive material such as ITO or IZO. The cathode 330 may have a different work function from the anode 310. For example, the work function of the cathode 330 may be less than the work function of the anode 310.

The cathode 330 may be electrically connected to the low voltage power line EVSS in the bezel area BZ. For example, the cathode 330 may be electrically connected to the low voltage power line EVSS in an area where the emission unit 320 is selectively removed.

The encapsulation structure 400 may be disposed in the active area AA in which the light-emitting element 300 is disposed in each pixel area and the bezel area BZ. The encapsulation structure 400 may prevent damage to the light emitting element 300 located in each pixel area due to external impact and moisture. For example, the light emitting element 300 in each pixel area may be completely covered by the encapsulation structure 400. The encapsulation structure 400 may extend to the bezel area BZ.

The encapsulation structure 400 may have a multilayer structure. For example, the encapsulation structure 400 may include the first encapsulation layer 410, the second encapsulation layer 420, and the third encapsulation layer 430 that are sequentially laminated. The first encapsulation layer 410, the second encapsulation layer 420, and the third encapsulation layer 430 may include insulating materials. The second encapsulation layer 420 may include a material different from the first encapsulation layer 410 and the third encapsulation layer 430. The second encapsulation layer 420 may include a material having relatively high fluidity. For example, the first encapsulation layer 410 and the third encapsulation layer 430 may be inorganic encapsulation layers made of an inorganic insulating material, and the second encapsulation layer 420 may be an organic encapsulation layer made of an organic insulating material.

The first encapsulation layer 410 may be positioned close to the cathode 330. For example, the first encapsulation layer 410 may be disposed to extend over the cathode 330 and to the dam DAM.

The second encapsulation layer 420 may be positioned on the first encapsulation layer 410. The second encapsulation layer 420 may be thicker than the first encapsulation layer 410. For example, steps caused by the light-emitting element 300 of each pixel area may be removed by the second encapsulation layer 420. The upper surface of the second encapsulation layer 420 facing the substrate 101 may be flat. The second encapsulation layer 420 may be filled up to the inside of the dam DAM.

The third encapsulation layer 430 may be positioned on the second encapsulation layer 420. The upper surface of the second encapsulation layer 420 may be covered by the third encapsulation layer 430. The light-emitting element 300 and the bank insulating film 150 of each pixel area may be completely covered by the encapsulation structure 400.

A method of manufacturing the display apparatus according to an embodiment of the present disclosure configured as described above will be described below.

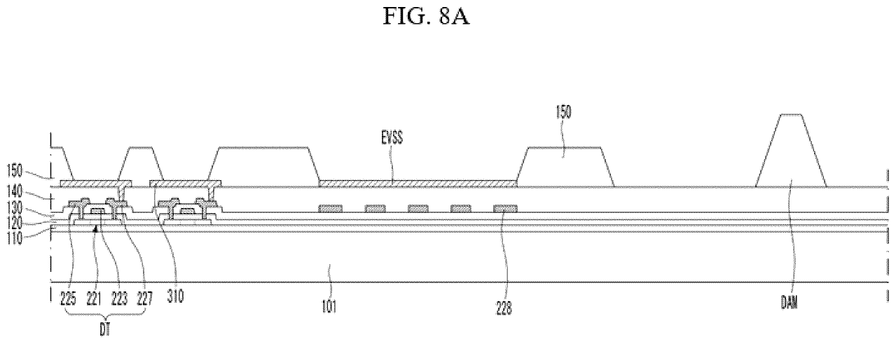

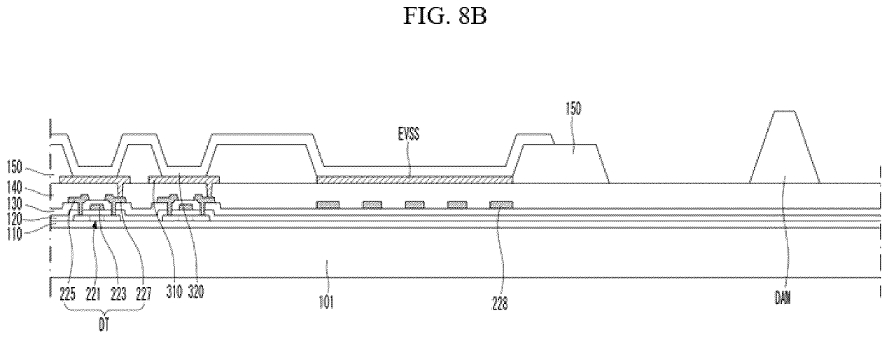

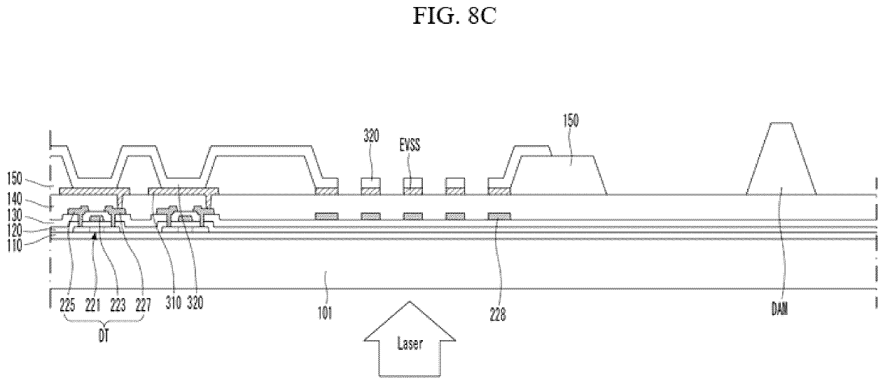

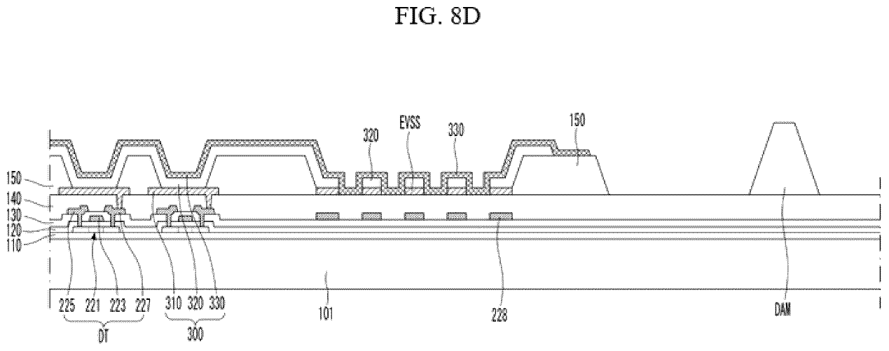

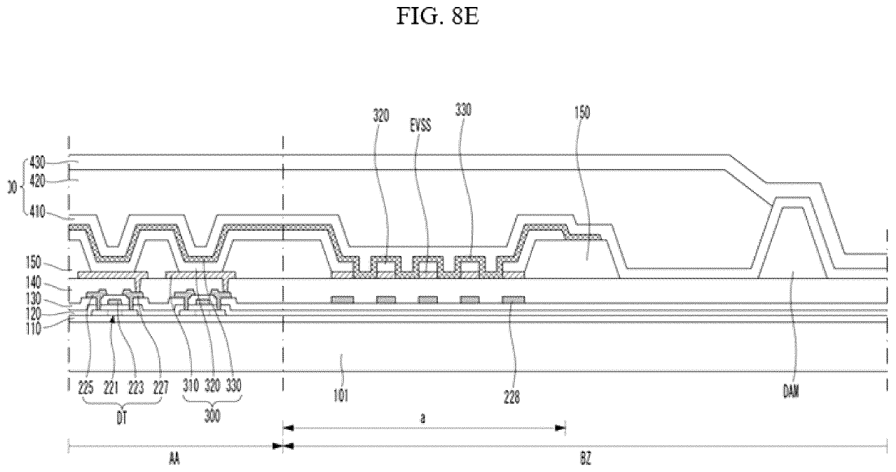

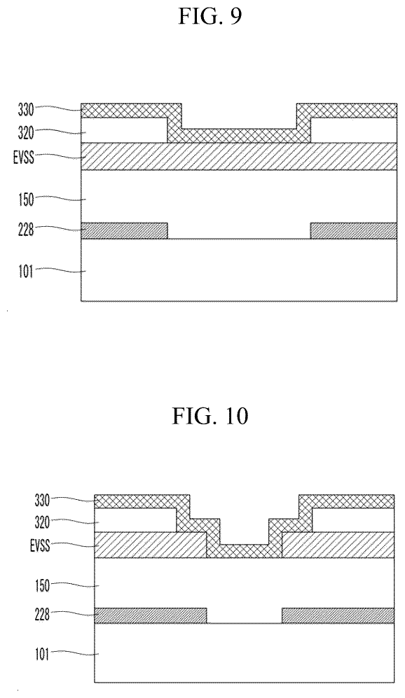

FIG. 8A to FIG. 8E are cross-sectional views illustrating a method of manufacturing the display apparatus according to an embodiment of the present disclosure. FIG. 9 is an enlarged cross-sectional view of one open portion 228b of the mask layer 228, and the low voltage power line EVSS, and the emission unit 320 formed according thereto according to the embodiment of the present disclosure.

As illustrated in FIG. 8A, the substrate 101 of the display panel 100 may be divided into an active area AA and a bezel area BZ. A buffer insulating film 110 may be formed on the substrate 101 of the active area AA and the bezel area BZ. The buffer insulating film 110 is formed to block penetration of moisture, etc. from the outside, and may be formed by laminating a silicon oxide (SiO₂) film and/or a silicon nitride (SiNx) film in multiple layers.

A transistor DT may be formed in each pixel area of the active area AA. The transistor illustrated in FIG. 8A corresponds to the driving transistor DT illustrated in FIG. 2. Therefore, not only the driving transistor DT but also the switching transistor ST, the storage capacitor Cst, and all the transistors constituting the compensation circuit CC illustrated in FIG. 2 may be formed in each pixel area. For convenience of description, only the driving transistor DT is illustrated.

The driving transistor DT may include the active layer 221, the gate electrode 223, the source electrode 227, and the drain electrode 225. The active layer 221 of the driving transistor DT may be disposed on the buffer insulating film 110. The active layer 221 may include a channel region, a source region disposed on one side of the channel region, and a drain region disposed on the other side of the channel region.

The active layer 221 may include a polycrystalline semiconductor. The source region and the drain region are conductive regions in which a polycrystalline semiconductor material is doped with impurity ions of Group 5 or Group 3, such as phosphorus (P) or boron (B), at a predetermined concentration. The channel region may provide a path for electrons or holes to move by maintaining the intrinsic state of the polycrystalline semiconductor material.

In another embodiment, the active layer 221 may contain an oxide semiconductor and may include an intrinsic channel region that is not doped with impurities and conductive source and drain regions doped with impurities. When the active layer 221 is made of an oxide semiconductor material, a light-shielding layer (not shown in the drawing) may be further provided under the active layer 221.

The gate insulating film 120 may be formed on the entire surface of the substrate 101 on which the active layer 221 is disposed. The gate insulating film 120 may be formed by laminating an inorganic layer such as a silicon oxide (SiO₂) film and/or a silicon nitride (SiNx) film in a single layer or multiple layers.

The gate electrode 223 may be formed on the gate insulating film 120 on the upper side of the active layer 221. The gate electrode 223 may be made of a metal material. For example, the gate electrode 223 may be a single layer or multiple layers of one or more of molybdenum (Mo), aluminum (Al), chromium (Cr), gold (Au), titanium (Ti), nickel (Ni), neodymium (Nd), and copper (Cu), and an alloy thereof, but the present disclosure is not limited thereto.

The interlayer insulating film 130 may be formed on each gate electrode 223. The interlayer insulating film 130 may be made of silicon oxide (SiO₂), silicon nitride (SiNx), or the like.

The drain electrode 225 and the source electrode 227 of the transistor may be formed on the interlayer insulating film 130 of each pixel area. The drain electrode 225 and the source electrode 227 may be electrically connected to the drain region and the source region of the active layer 221 through contact holes formed in the interlayer insulating film 130. The drain electrode 225 and the source electrode 227 may include a conductive material. For example, the drain electrode 225 and the source electrode 227 may include a metal such as aluminum (Al), chromium (Cr), copper (Cu), molybdenum (Mo), titanium (Ti), or tungsten (W). The drain electrode 225 and the source electrode 227 may be insulated from the gate electrode 223. The drain electrode 225 and the source electrode 227 may include a different material from the gate electrode 223.

Meanwhile, in the bezel area BZ, the mask layer 228 may be formed of the same material as the drain electrode 225 and the source electrode 227 on the interlayer insulating film 130. However, the present disclosure is not limited thereto. The mask layer 228 may be formed of a different material from the drain electrode 225 and the source electrode 227. For example, the mask layer 228 may be formed of the same material as the gate electrode 223 on the gate insulating film 130. When the active layer 221 is made of an oxide semiconductor material, the mask layer 228 may be formed of the same material as the light-shielding layer (not shown in the drawing) disposed under the active layer 221. The mask layer 228 may be disposed in the first EL tolerance area a of the bezel area BZ described in FIG. 3.

The mask layer 228 may be configured in various shapes as shown in FIG. 5 to FIG. 7. The mask layer 228 may have a plurality of open portions 228b disposed in various shapes in the mask body 228a. For example, as shown in FIG. 5, each of the plurality of open portions 228b may be formed in a circular shape. As shown in FIG. 6, each of the plurality of open portions 228b may be formed in a rectangular shape. As shown in FIG. 7, each of the plurality of open portions 228b may be formed in a cross shape. The mask layer 228 may be formed to be thicker than the low voltage power line EVSS which will be formed later.

The planarization film 140 may be formed on the entire surface of the substrate including the driving transistor DT and the mask layer 228 disposed as described above. The planarization film 140 can eliminate steps caused by the driving transistor DT and the mask layer 228. For example, the drain electrode 225 and the source electrode 227 of each pixel area and the mask layer 228 may be covered by the planarization film 140. The upper surface of the planarization film 140 facing the substrate 101 may be flat. For example, the upper surface of the planarization film 140 may be parallel to the upper surface of the substrate 101. The planarization film 140 may include an insulating material. The planarization film 140 may include a material having relatively high fluidity. For example, the planarization film 140 may be an organic insulating film made of an organic insulating material.

The anode 310 of the light-emitting element 300 may be formed on the planarization film 140 of each pixel area. The anode 310 may be independently formed on the planarization film 140 of each pixel area. Each anode 310 may be electrically connected to the source electrode 227 of the driving transistor DT through a contact hole formed in the planarization film 140. The anode 310 may include a conductive material. The anode 310 may include a material having relatively high reflectivity. For example, the anode 310 may include a metal such as aluminum (Al) or silver (Ag). The anode 310 may have a multilayer structure. For example, the anode 310 may have a structure in which a reflective electrode made of metal is positioned between transparent electrodes made of transparent conductive materials such as ITO and IZO.

The low voltage power line EVSS may be formed on the planarization film 140 of the bezel area BZ. The low voltage power line EVSS may overlap the mask layer 228. The low voltage power line EVSS may be disposed in the first EL tolerance area a of the bezel area BZ described in FIG. 3. For example, the low voltage power line EVSS may be formed of the same material as the anode 310. However, the present disclosure is not limited thereto, and the low voltage power line EVSS may be formed of a different material from the anode 310.

The bank insulating film 150 may be formed on the planarization film 140 on which the anode 310 and the low voltage power line EVSS are formed. The bank insulating film 150 may be formed on the planarization film 140 to cover the edges of each anode 310. The bank insulating film 150 may define the emission area EA within each pixel area. For example, the anode 310 overlapping the emission area EA of each pixel area may be exposed by the bank insulating film 150. The emission area EA of each pixel area may be surrounded by the bank insulating film 150. The anode 310 of each pixel area may be insulated from the anode 310 of an adjacent pixel area by the bank insulating film 150.

In addition, the bank insulating film 150 may be formed on the planarization film 140 to cover the edges of the low voltage power line EVSS. For example, the low voltage power line EVSS may be exposed by the bank insulating film 150. The low voltage power line EVSS may be surrounded by the bank insulating film 150. The bank insulating film 150 may include an insulating material. For example, the bank insulating film 150 may be an organic insulating film made of an organic insulating material. The bank insulating film 150 may include a different material from the planarization film 140.

When the bank insulating film 150 is formed, a dam DAM may be formed at the outermost edge of the bezel area BZ. The dam DAM may be formed to be higher than the bank insulating film 150 disposed in the active area AA and the bezel area BZ.

As illustrated in FIG. 8B, the emission unit 320 is formed on the anode 310 and the bank insulating film 150. The emission unit 320 may be formed to extend not only to the active area AA but also to the first EL tolerance area a of the bezel area BZ described in FIG. 3. The emission unit 320 may be in direct contact with each anode 310. The emission unit 320 may also be formed on the low voltage power line EVSS exposed by the bank insulating film 150.

For example, the emission unit 320 may include an emission material layer (EML). The emission material layer may include an organic emission material, an inorganic emission material, or a hybrid emission material. For example, the display apparatus according to the embodiment of the present disclosure may be an organic light emitting display apparatus including an organic emission material. The emission unit 320 may have a multilayer structure. For example, the emission unit 320 may further include at least one of a hole injection layer (HIL), a hole transport layer (HTL), an electron transport layer (ETL), and an electron injection layer (EIL).

The emission material layer (EML) of the emission unit 320 may be independently disposed on the anode 310 of the emission area EA of each pixel area. At least one of the hole injection layer (HIL), the hole transport layer (HTL), the electron transport layer (ETL), and the electron injection layer (EIL) of the emission unit 320 may be commonly disposed in all pixel areas. That is, at least one of the hole injection layer (HIL), the hole transport layer (HTL), the electron transport layer (ETL), and the electron injection layer (EIL) of the emission unit 320 may be commonly disposed on the bank insulating film 150 not only in the active area AA but also in the first EL tolerance area a of the bezel area BZ described in FIG. 3.

As shown in FIG. 8C, on the side of the substrate 101, a laser is radiated to the low voltage power line EVSS and the emission unit 320 formed on the low voltage power line EVSS using the mask layer 228 as a mask to selectively remove at least the emission unit 320 formed on the low voltage power line EVSS. For example, the emission unit 320 may be selectively removed by Joule heating of the laser. This will be described in more detail with reference to FIG. 9.

In another embodiment, not only the emission unit 320 on the upper side of the mask layer 228 but also the low voltage power line EVSS may be selectively removed. For example, by controlling the intensity (energy) of the laser and radiating the laser under the mask layer 228, portions of the low voltage power line EVSS and the emission unit 320 corresponding to the plurality of open portions 228b of the mask layer 228 can be selectively removed. In FIG. 8C, an embodiment is illustrated in which both the low voltage power line EVSS and the emission unit 320 in areas corresponding to the plurality of open portions 228b of the mask layer 228 are selectively removed. This will be described in more detail with reference to FIG. 10.

As illustrated in FIG. 8D, the cathode 330 is formed on the emission unit 320 and the bank insulating film 150. The cathode 330 may include a conductive material. The cathode 330 may include a different material from the anode 310. The transmittance of the cathode 330 may be greater than that of the anode 310. The cathode may be a transparent electrode made of a transparent conductive material such as ITO or IZO. The cathode 330 may have a different work function from the anode 310. For example, the work function of the cathode 330 may be less than the work function of the anode 310.

The cathode 330 may be electrically connected to the low voltage power line EVSS in the bezel area BZ. This will be described in more detail with reference to FIG. 9 and FIG. 10.

As illustrated in FIG. 8E, the encapsulation structure 400 is formed on the active area AA in which the light-emitting element 300 is disposed in each pixel area and the bezel area BZ.

For example, the first encapsulation layer 410 is formed on the cathode 330, the bank insulating film 150 of the bezel area BZ, and the outer surface of the dam DAM. The second encapsulation layer 420 is formed on the first encapsulation layer 410. The second encapsulation layer 420 may be thicker than the first encapsulation layer 410. For example, steps caused by the light-emitting element 300 of each pixel area may be removed by the second encapsulation layer 420. The second encapsulation layer 420 may be filled up to the inner side of the dam DAM. Then, the third encapsulation layer 430 is formed on the second encapsulation layer 420. The first encapsulation layer 410, the second encapsulation layer 420, and the third encapsulation layer 430 may include insulating materials. The second encapsulation layer 420 may include a different material from the first encapsulation layer 410 and the third encapsulation layer 430. The second encapsulation layer 420 may include a material having relatively high fluidity. For example, the first encapsulation layer 410 and the third encapsulation layer 430 may be inorganic encapsulation layers made of inorganic insulating materials, and the second encapsulation layer 420 may be an organic encapsulation layer made of an organic insulating material.

FIG. 9 is an enlarged cross-sectional view of one open portion 228b of the mask layer 228, and the low voltage power line EVSS, the emission unit 320, and the cathode 330 formed according to the open portion 228b according to an embodiment of the present disclosure.

For example, by controlling the intensity (energy) of the laser and radiating the laser under the mask layer 228, the portions of the emission unit 320 corresponding to the plurality of open portions 228b of the mask layer 228 are heated, and the heated portions of the emission unit 320 can be selectively removed.

When only the emission unit 320 is selectively removed in this manner, the cathode 330 can be electrically connected to the upper surface of the low voltage power line EVSS in the areas where the emission unit 320 is selectively removed.

FIG. 10 is an enlarged cross-sectional view of one open portion 228b of the mask layer 228, and the low voltage power line EVSS, the emission unit 320, and the cathode 330 formed according thereto according to another embodiment of the present disclosure.

In another embodiment, not only the emission unit 320 on the upper side of the mask layer 228, but also the low voltage power line EVSS may be selectively removed. For example, by controlling the intensity (energy) of the laser and radiating the laser under the mask layer 228, the portions of the low voltage power line EVSS and the emission unit 320 corresponding to the plurality of open portions 228b of the mask layer 228 can be selectively removed. At this time, the removed portions of the emission unit 320 may be wider than the removed portions of the low voltage power line EVSS. For example, the width of a removed portion of the emission unit 320 may be greater than the width of a removed portion of the low voltage power line EVSS. Therefore, the low voltage power line EVSS and the emission unit 320 can have steps in the areas corresponding to the open portions 228b of the mask layer 228. The mask layer 228 may be formed thicker than the low voltage power line EVSS.

As described in FIG. 10, when the emission unit 320 and the low voltage power line EVSS are selectively removed, the cathode 330 can be electrically connected to the upper surface and the side surface of the low voltage power line EVSS in the areas where the emission unit 320 is selectively removed.

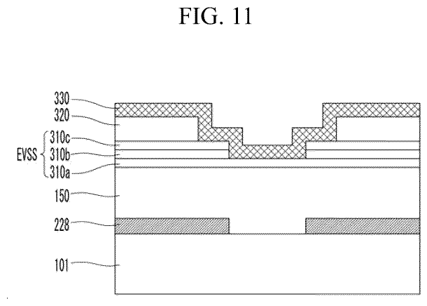

FIG. 11 is an enlarged cross-sectional view of one open portion 228b of the mask layer 228, and the low voltage power line EVSS, the emission unit 320, and the cathode 330 formed according to the open portion 228b according to another embodiment of the present disclosure.

FIG. 11 illustrates an embodiment in which the low voltage power line EVSS is formed of the same material as the anode 310 and the anode 310 has a multilayer structure.

For example, the low voltage power line EVSS and the anode 310 may have a structure in which a reflective electrode made of metal is positioned between transparent electrodes made of transparent conductive materials such as ITO and IZO. For example, the low voltage power line EVSS and the anode 310 may be formed in a structure in which a first transparent conductive layer 310a, a metal layer 310b, and a second transparent conductive layer 310c are laminated.

With this structure, if the output of the laser is adjusted to be reduced, the first transparent conductive layer 310a of the low voltage power line EVSS corresponding to the plurality of open portions of the mask layer 228 remains, and portions of the metal layer 310b and the second transparent conductive layer 310c corresponding to the plurality of open portions of the mask layer 228 can be removed, as illustrated in FIG. 11. In addition, portions of the emission unit 320 corresponding to the plurality of open portions of the mask layer 228 can be removed.

At this time, the removed portions of the emission unit 320 may be wider than the removed portions of each of the metal layer 310b of the low voltage power line EVSS and the second transparent conductive layer 310c of the low voltage power line EVSS.

As described in FIG. 11, when the emission unit 320 and the metal layer 310b and the second transparent conductive layer 310c of the low voltage power line EVSS are removed with different widths, the cathode 330 can be electrically connected to the upper surface of the second transparent conductive layer 310c of the low-voltage power line EVSS and the side surfaces of the metal layer 310b and the second transparent conductive layer 310c of the low voltage power line EVSS, and the upper surface of the first transparent conductive layer 310a of the low voltage power line EVSS in the areas where the emission unit 320 is selective removed.

As described above, the mask layer 228 having a plurality of open portions and the low voltage power line EVSS are disposed in the process margin area of the common emission layer in the bezel area BZ, and a laser is radiated thereto using the mask layer 228 as a mask. Then, portions of the emission unit 320 corresponding to the open portions of the mask layer 228 are selectively removed due to Joule heating of the laser, or both the emission unit 320 and the low voltage power line EVSS corresponding to the open portions of the mask layer 228 are selectively removed.

Then, the cathode is electrically connected to the low voltage power line EVSS. Therefore, since the cathode 330 and the low voltage power line EVSS are electrically connected in the process margin area of the common emission layer, there is no need to separately design the first EL tolerance area a and the cathode contact area c in the bezel area BZ, as shown in FIG. 3, and thus a narrow bezel of the display apparatus can be achieved.

In addition, since the bezel area can be reduced, the active area of the display panel can be maximized.

The display apparatus according to various embodiments of the present disclosure can be described as follows.

The display apparatus according to an embodiment of the present disclosure may include a substrate having an active area having a plurality of pixel areas and a bezel area around the active area, a mask layer positioned on the substrate in the bezel area and having a plurality of open portions, a planarization layer formed on the entire surface of the substrate including the mask layer, an anode of a light-emitting element positioned on the planarization layer of each of the plurality of pixel areas, a low voltage power line positioned on the planarization layer of the bezel area to overlap the mask layer, a bank insulating film positioned on the planarization layer to expose the anode and the low voltage power line, an emission unit of the light-emitting element positioned over the active area and the low voltage power line of the bezel area, portions of the emission unit corresponding to the plurality of open portions of the mask layer being removed, and a cathode of the light-emitting element positioned on the emission unit of the light-emitting element and electrically connected to the low voltage power line.

According to an embodiment of the present disclosure, portions of the low voltage power line corresponding to the plurality of open portions of the mask layer may be removed.

According to an embodiment of the present disclosure, the removed portions of the emission unit corresponding to the plurality of open portions of the mask layer may be wider than the removed portions of the low voltage power line corresponding to the open portions of the mask layer.

According to an embodiment of the present disclosure, the bezel area may have a first area in which the mask layer, the low voltage power line, and the emission unit of the light-emitting element are disposed, a second area in which the cathode extends, and a third area in which the cathode does not extend sequentially from the active area to the outermost side.

According to an embodiment of the present disclosure, a transistor having an active layer, a gate electrode, a source electrode, and a drain electrode may be further provided below the anode of each light-emitting element, and the mask layer may include the same material as the gate electrode or the source electrode and the drain electrode of the transistor.

According to an embodiment of the present disclosure, a light-shielding layer may be further provided below the active layer of the transistor, and the mask layer may include the same material as the light-shielding layer.

According to an embodiment of the present disclosure, the low voltage power line may include the same material as the anode.

According to an embodiment of the present specification, the low voltage power line and the anode may include a structure in which a first transparent conductive layer, a metal layer, and a second transparent conductive layer are laminated, portions of the first transparent conductive layer of the low voltage power line corresponding to the plurality of open portions of the mask layer may remain, and portions of the metal layer and the second transparent conductive layer of the low voltage power line corresponding to the plurality of open portions of the mask layer may be selectively removed.

According to an embodiment of the present disclosure, the removed portions of the emission unit of the light-emitting element corresponding to the plurality of open portions of the mask layer may be wider than the removed portions of each of the metal layer and the second transparent conductive layer of the low voltage power line corresponding to the open portions of the mask layer.

According to an embodiment of the present disclosure, an encapsulation structure disposed on the cathode may be further provided.

A method of manufacturing a display apparatus according to an embodiment of the present disclosure may include forming a thin film transistor in each pixel area of a substrate having an active area having a plurality of pixel areas and a bezel area around the active area, forming a mask layer having a plurality of open portions on the substrate in the bezel area, forming a planarization layer on the entire surface of the substrate including the thin film transistor and the mask layer, forming an anode of a light-emitting element on the planarization layer of each of the plurality of pixel areas such that the anode is electrically connected to the thin film transistor, forming a low voltage power line on the planarization layer of the bezel area such that the low voltage power line overlaps the mask layer, forming a bank insulating film on the planarization layer to expose the anode and the low voltage power line, forming an emission unit of the light-emitting element over the active area and the low voltage power line of the bezel area, selectively removing portions of the emission unit of the light-emitting element corresponding to the plurality of open portions of the mask layer by radiating a laser from a side of the substrate using the mask layer as a mask, and forming a cathode of the light-emitting element on the emission unit of the light-emitting element and the bezel area such that the cathode is electrically connected to the low voltage power line.

The display apparatus and the method of manufacturing the same according to embodiments of the present disclosure have the following effects.

It is possible to achieve a narrow bezel by disposing a laser mask and a voltage supply line (or a power line) in the process margin area of the common emission layer of the bezel area, selectively removing the voltage supply line and the common emission layer using a laser lift-off method, and then electrically connecting the cathode to the voltage supply line.

It is possible to prevent damage to transistors and wiring since a laser is radiated through a mask layer. In addition, it is possible to secure a sufficient margin related to the laser beam size and processing tolerance since the laser is radiated through a mask layer.

It is possible to maximize the active area in the display panel since the bezel area can be reduced.

The effects according to the embodiments are not limited to the effects described above, and more diverse effects are included in the present disclosure.

It will be apparent to those skilled in the art that various modifications and variations can be made in the display apparatus and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display apparatus, comprising:
a substrate including an active area having a plurality of pixel areas and a bezel area around the active area;
a mask layer positioned on the substrate in the bezel area and having a plurality of open portions;
a planarization layer formed on an entire surface of the substrate including the mask layer;
an anode of a light-emitting element positioned on the planarization layer of each of the plurality of pixel areas;
a low voltage power line positioned on the planarization layer of the bezel area to overlap the mask layer;
a bank insulating film positioned on the planarization layer to expose the anode and the low voltage power line;
an emission unit of the light-emitting element positioned over the active area and the low voltage power line of the bezel area, portions of the emission unit corresponding to the plurality of open portions of the mask layer being removed; and
a cathode of the light-emitting element positioned on the emission unit of the light-emitting element and electrically connected to the low voltage power line.

2. The display apparatus of claim 1, wherein portions of the low voltage power line corresponding to the plurality of open portions of the mask layer are removed.

3. The display apparatus of claim 2, wherein the removed portions of the emission unit corresponding to the plurality of open portions of the mask layer are wider than the removed portions of the low voltage power line corresponding to the open portions of the mask layer.

4. The display apparatus of claim 1, wherein the bezel area has a first area in which the mask layer, the low voltage power line, and the emission unit of the light-emitting element are disposed, a second area in which the cathode extends, and a third area in which the cathode does not extend sequentially from the active area to the outermost side.

5. The display apparatus of claim 1, further comprising a transistor having an active layer, a gate electrode, a source electrode, and a drain electrode below the anode of each light-emitting element,
wherein the mask layer includes the same material as the gate electrode or the source electrode and the drain electrode of the transistor.

6. The display apparatus of claim 5, further comprising a light-shielding layer below the active layer of the transistor,
wherein the mask layer includes the same material as the light-shielding layer.

7. The display apparatus of claim 1, wherein the low voltage power line includes the same material as the anode.

8. The display apparatus of claim 7, wherein the low voltage power line and the anode include a structure in which a first transparent conductive layer, a metal layer, and a second transparent conductive layer are laminated,
wherein portions of the first transparent conductive layer of the low voltage power line corresponding to the plurality of open portions of the mask layer remain, and portions of the metal layer and the second transparent conductive layer of the low voltage power line corresponding to the plurality of open portions of the mask layer are removed.

9. The display apparatus of claim 8, wherein the removed portions of the emission unit of the light-emitting element corresponding to the plurality of open portions of the mask layer are wider than the removed portions of each of the metal layer and the second transparent conductive layer of the low voltage power line corresponding to the open portions of the mask layer.

10. The display apparatus of claim 1, further comprising an encapsulation structure disposed on the cathode.

11. A method of manufacturing a display apparatus, comprising:
forming a thin film transistor in each pixel area of a substrate including an active area having a plurality of pixel areas and a bezel area around the active area;
forming a mask layer having a plurality of open portions on the substrate in the bezel area;
forming a planarization layer on an entire surface of the substrate including the thin film transistor and the mask layer;
forming an anode of a light-emitting element on the planarization layer of each of the plurality of pixel areas such that the anode is electrically connected to the thin film transistor;
forming a low voltage power line on the planarization layer of the bezel area such that the low voltage power line overlaps the mask layer;
forming a bank insulating film on the planarization layer to expose the anode and the low voltage power line;
forming an emission unit of the light-emitting element over the active area and the low voltage power line of the bezel area;
removing portions of the emission unit of the light-emitting element corresponding to the plurality of open portions of the mask layer by radiating a laser from a side of the substrate using the mask layer as a mask; and
forming a cathode of the light-emitting element on the emission unit of the light-emitting element and the bezel area such that the cathode is electrically connected to the low voltage power line.

12. The method of claim 11, further comprising removing portions of the low voltage power line corresponding to the plurality of open portions of the mask layer by radiating a laser from the side of the substrate using the mask layer as a mask.

13. The method of claim 12, wherein the removed portions of the emission unit corresponding to the plurality of open portions of the mask layer are wider than the removed portions of the low voltage power line corresponding to the open portions of the mask layer.

14. The method of claim 11, wherein the bezel area has a first area in which the mask layer, the low voltage power line, and the emission unit of the light-emitting element are disposed, a second area in which the cathode extends, and a third area in which the cathode does not extend sequentially from the active area to the outermost side.

15. The method of claim 11, wherein a transistor having an active layer, a gate electrode, a source electrode, and a drain electrode is further provided below the anode of each light-emitting element,
wherein the mask layer includes the same material as the gate electrode or the source electrode and the drain electrode of the transistor.

16. The method of claim 15, wherein a light-shielding layer is further provided below the active layer of the transistor,
wherein the mask layer includes the same material as the light-shielding layer.

17. The method of claim 11, wherein the low voltage power line includes the same material as the anode.

18. The method of claim 7, wherein the low voltage power line and the anode include a structure in which a first transparent conductive layer, a metal layer, and a second transparent conductive layer are laminated,
wherein portions of the first transparent conductive layer of the low voltage power line corresponding to the plurality of open portions of the mask layer remain, and portions of the metal layer and the second transparent conductive layer of the low voltage power line corresponding to the plurality of open portions of the mask layer are removed.

19. The method of claim 18, wherein the removed portions of the emission unit of the light-emitting element corresponding to the plurality of open portions of the mask layer are wider than the removed portions of each of the metal layer and the second transparent conductive layer of the low voltage power line corresponding to the open portions of the mask layer.

20. The method of claim 11, further comprising forming an encapsulation structure on the cathode.
